(19) United States
(12) Patent Application Publication
(10) Pub. No.: US 2015/0349012 A1
(43) Pub. Date: Dec. 3, 2015

(54) SOLID-STATE IMAGE PICKUP DEVICE AND IMAGE PICKUP DEVICE

(71) Applicant: OLYMPUS CORPORATION, Tokyo (JP)

(72) Inventor: Kenji Kobayashi, Tokyo (JP)

(73) Assignee: OLYMPUS CORPORATION, Tokyo (JP)

(21) Appl. No.: 14/822,308

(22) Filed: Aug. 10, 2015

Related U.S. Application Data
(63) Continuation of application No. PCT/JP2014/050809, filed on Jan. 17, 2014.

(30) Foreign Application Priority Data
Feb. 14, 2013 (JP) 2013-026814

(51) Int. Cl. H01L 27/146

(52) U.S. Cl. CPC H01L 27/14634; H01L 27/14636

(57) ABSTRACT

Provided is a solid-state image pickup device in which a first substrate and a second substrate are laminated and electrically connected by connection units. The first substrate includes: a plurality of pixel units which are disposed in a matrix shape and output signals corresponding to amounts of incident light; and first wiring units which connect the pixel units and the connection units. The second substrate includes: column processing circuits which process the signals generated by the pixel units; and second wiring units which connect the connection units and the column processing circuits. Sum of a wiring resistance of a first wiring unit and a wiring resistance of a second wiring unit are almost identical in each column.

### CROSS REFERENCE TO RELATED APPLICATIONS

This application is a continuation application based on a PCT Patent Application No. PCT/JP2014/050809, filed Jan. 17, 2014, whose priority is claimed on Japanese Patent Application No. 2013-026814, filed Feb. 14, 2013, the entire content of which are hereby incorporated by reference.

### BACKGROUND OF THE INVENTION

1. Field of the Invention

The present invention relates to a solid-state image pickup device and an image pickup device.

2. Description of the Related Art

In recent years, video cameras, electronic still cameras, and the like have come into wide general use. In these cameras, charge coupled device (CCD)-type and complementary metal oxide semiconductor (CMOS)-type image pickup devices (solid-state image pickup elements) are used. A solid-state image pickup device has a plurality of pixels disposed in a two-dimensional matrix shape, and a photoelectric conversion unit disposed in each pixel generates and accumulates charges corresponding to incident light.

Japanese Unexamined Patent Application, First Publication No. 2012-104684 discloses a solid-state image pickup device in which a first substrate having photoelectric conversion units formed therein and a second substrate having a plurality of metal oxide semiconductor (MOS) transistors formed therein are bonded together and the first substrate and the second substrate are electrically connected by connection electrodes. In the solid-state image pickup device, the photoelectric conversion units formed in the first substrate accumulate signal charges corresponding to the amount of incident light. The accumulated signal charges are input to the second substrate through the connection electrodes. The signal charges input to the second substrate perform predetermined signal processing by means of a processing circuit formed in the second substrate.

### SUMMARY

According to a first aspect of the present invention, a solid-state image pickup device is provided in which a first substrate and a second substrate are laminated and electrically connected by connection units. The first substrate includes: a plurality of pixel units which are disposed in a matrix shape and output signals corresponding to amounts of incident light; and first wiring units which connect the pixel units and the connection units. The second substrate includes: column processing circuits which process the signals generated by the pixel units; and second wiring units which connect the connection units and the column processing circuits. Sum of a wiring resistance of a first wiring unit and a wiring resistance of a second wiring unit are almost identical in each column.

According to a second aspect of the present invention, in the solid-state image pickup device relating to the first aspect, sum of a wiring length of a first wiring unit and a wiring length of a second wiring unit are almost identical in each column.

According to a third aspect of the present invention, an image pickup device may include the solid-state image pickup device relating to the first aspect or the second aspect.

### BRIEF DESCRIPTION OF THE DRAWINGS

FIG. 1 is a schematic diagram of a solid-state image pickup device of a first embodiment.

FIG. 2 is a schematic diagram of a first substrate of the solid-state image pickup device of the first embodiment.

FIG. 3 is a schematic diagram of a second substrate of the solid-state image pickup device of the first embodiment.

FIG. 4 is a schematic diagram of a second substrate of the solid-state image pickup device of the first embodiment.

FIG. 5 is a diagram showing a circuit configuration of a pixel unit of the solid-state image pickup device of the first embodiment.

FIG. 6 is a timing chart showing operation of the solid-state image pickup device of the first embodiment.

FIG. 7A is a diagram showing wirings from pixel units of the solid-state image pickup device of the first embodiment to a column processing circuit.

FIG. 7B is a diagram showing wirings from pixel units of the solid-state image pickup device of the first embodiment to a column processing circuit.

FIG. 8 is a block diagram showing a schematic configuration of an image pickup device equipped with the solid-state image pickup device of the first embodiment.

### DETAILED DESCRIPTION OF THE PREFERRED EMBODIMENTS

### First Embodiment

Hereinafter, with reference to the drawings, a first embodiment of the present invention will be described. FIG. 1 is a schematic diagram of a solid-state image pickup device in the present embodiment.

A solid-state image pickup device 1 shown in FIG. 1 has a first substrate 10, a second substrate 20, and connection units 30.

The first substrate 10 is formed of an insulator or a semiconductor in a plate shape or a sheet shape having a predetermined thickness. As the insulator and the semiconductor constituting the first substrate, for example, silicon, a resin, a ceramic, glass, and the like are exampled.

Like the first substrate 10, the second substrate 20 is formed of an insulator or a semiconductor in a plate shape or a sheet shape having a predetermined thickness.

The connection units 30 electrically connect the first substrate 10 and the second substrate 20, and are constituted by bumps of gold, solder, or the like.

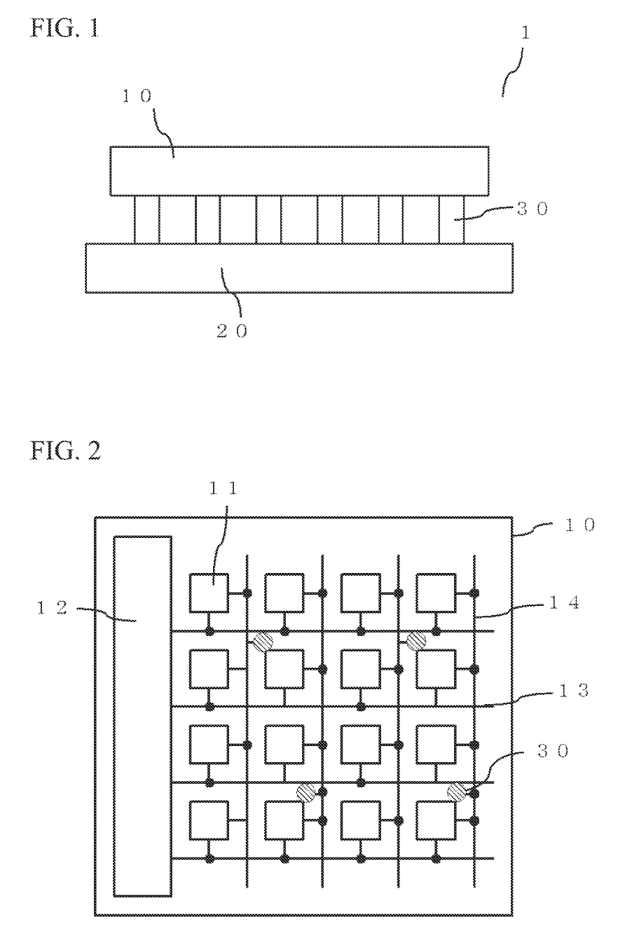

FIG. 2 is a schematic diagram of the first substrate 10 of the solid-state image pickup device 1 of the present embodiment. The first substrate 10 has pixel units 11, a vertical scanning circuit 12, control signal lines 13, and vertical signal lines 14.

The plurality of pixel units 11 generate signals (pixel signals) corresponding to the amounts of incident light, and are arranged in a matrix shape in the first substrate 10. In FIG. 2, 16 pixel units 11 are arranged in four rows×four columns, but the pixel array shown in FIG. 2 is an example. The number of rows and columns may be equal to or larger than two.

The vertical scanning circuit 12 is constituted by, for example, a shift register, and performs drive control of the pixel units 11 in units of rows. In this drive control, a reset operation, an accumulation operation, a signal readout operation, and the like of the pixel units 11 are included. In order to perform this drive control, the vertical scanning circuit 12 outputs control signals (control pulses) to respective pixel units 11 through a control signal line 13 provided for each row, and controls pixel units 11 in each row. The vertical scanning circuit 12 performs the drive control, so that pixel signals are output from pixel units 11 to a vertical signal line 14 provided for each column. The pixel signals output to the vertical signal line 14 are input to the second substrate 20 through a connection unit 30.

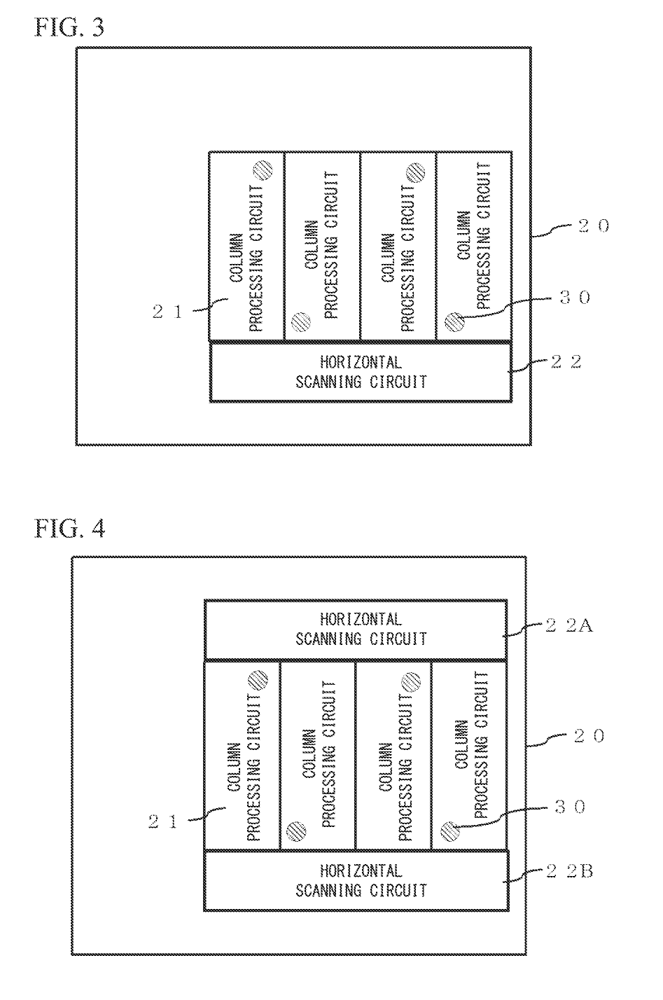

FIG. 3 is a schematic diagram of the second substrate 20 of the solid-state image pickup device 1 of the present embodiment. The second substrate 20 has column processing circuits 21 and a horizontal scanning circuit 22.

The column processing circuits 21 are connected to the vertical signal lines 14 of the respective columns through the connection units 30, and perform signal processing including analog digital conversion (A/D conversion) on pixel signals output from the pixel units 11.

The horizontal scanning circuit 22 is constituted by, for example, a shift register, and selects pixel columns from which pixel signals will be read out, sequentially selects column processing circuits 21 relating to the selected pixel columns, and sequentially outputs the pixel signals to the column processing circuits 21. In FIG. 3, an example in which there is the one horizontal scanning circuit 22 is shown, but as shown in FIG. 4, two horizontal scanning circuits may be disposed. In this case, for example, one horizontal scanning circuit 22A performs readout of pixel signals in column processing circuits 21 of odd numbered columns, and the other horizontal scanning circuit 22B performs readout of pixel signals in column processing circuits 21 of even numbered columns.

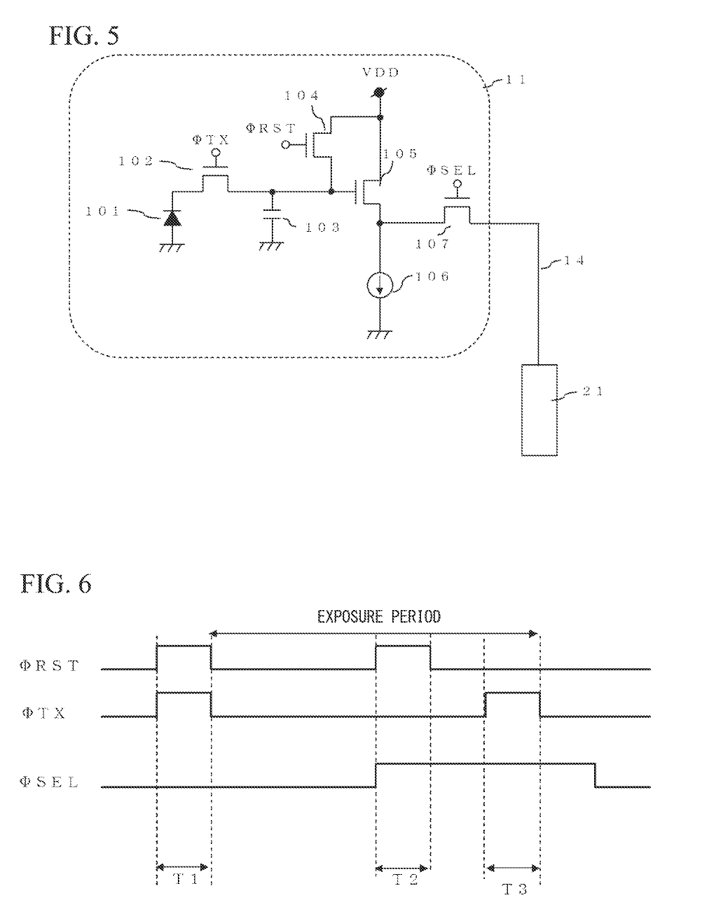

FIG. 5 is a diagram showing a circuit configuration of a pixel unit 11 of the solid-state image pickup device of the present embodiment. The pixel unit 11 has a photoelectric conversion element 101, a transmission transistor 102, a floating diffusion (FD) 103, a reset transistor 104, an amplification transistor 105, a current source 106, and a selection transistor 107.

A first end of the photoelectric conversion element 101 is grounded. The drain terminal of the transmission transistor 102 is connected to a second end of the photoelectric conversion element 101. The gate terminal of the transmission transistor 102 is connected to the vertical scanning circuit 12, so that a transmission pulse φTX is supplied.

A first end of FD 103 is connected to the source terminal of the transmission transistor 102. A second end of the FD 103 is grounded.

The source terminal of the reset transistor 104 is connected to the source terminal of the transmission transistor 102. The drain terminal of the reset transistor 104 is connected to a power supply voltage VDD. The gate terminal of the reset transistor 104 is connected to the vertical scanning circuit 12, so that a reset pulse φRST is supplied.

The drain terminal of the amplification transistor 105 is connected to the power supply voltage VDD. The gate terminal which is an input portion of the amplification transistor 105 is connected to the source terminal of the transmission transistor 102. A first end of the current source 106 is connected to the source terminal of the amplification transistor 105, and a second end of the current source 106 is grounded.

The drain terminal of the selection transistor 107 is connected to the source terminal of the amplification transistor 105, and the source terminal of the selection transistor 107 is connected to a column processing circuit 21. The gate terminal of the selection transistor 107 is connected to the vertical scanning circuit 12, so that a selection pulse φSEL is supplied.

The photoelectric conversion element 101 is, for example, a photodiode, and generates (produces) signal charges based on incident light and holds and accumulates the generated (produced) signal charges.

The transmission transistor 102 is a transistor that transmits the signal charges accumulated in the photoelectric conversion element 101 to the FD 103. On/off of the transmission transistor 102 is controlled by the transmission pulse φTX from the vertical scanning circuit 12.

The FD 103 is a capacity that temporarily holds and accumulates the signal charges transmitted from the photoelectric conversion element 101.

The reset transistor 104 is a transistor that resets the FD 103. On/off of the reset transistor 104 is controlled by the reset pulse φRST from the vertical scanning circuit 12. By simultaneously turning on the reset transistor 104 and the transmission transistor 102, it is also possible to reset the photoelectric conversion element 101. Reset of the FD 103 or the photoelectric conversion element 101 is to set the state (an electric potential) of the FD 103 or the photoelectric conversion element 101 to a reference state (a reference potential, a reset level).

The amplification transistor 105 is a transistor that outputs an amplified signal obtained by amplifying a signal based on the signal charges accumulated in the FD 103 from the source terminal.

The current source 106 functions as a load of the amplification transistor 105 and supplies current, which drives the amplification transistor 105, to the amplification transistor 105. The amplification transistor 105 and the current source 106 constitute a source follower circuit.

The selection transistor 107 is a transistor that selects the pixel unit 11 and transfers the output signal of the amplification transistor 105 to a vertical signal line 14. On/off of the selection transistor 107 is controlled by the selection pulse φSEL from the vertical scanning circuit 12.

The amplified signal output from the amplification transistor 105 disposed in the first substrate 10 is output to the second substrate 20 through a connection unit 30 and input to the column processing circuit 21.

FIG. 6 shows control signals supplied from the vertical scanning circuit 12 to pixel units 11 in each row. Operation of the pixel units 11 in time periods T1 to T3 shown in FIG. 6 will be described below.

(Operation of Time Period T1)

First, the transmission pulse φTX changes from a Low (L) level to a High (H) level, so that the transmission transistors 102 are put in an ON state. At the same time, the reset pulse φRST changes from the L level to the H level, so that the reset transistors 104 are put in the ON state. Accordingly, the photoelectric conversion elements 101 are reset.

Subsequently, the transmission pulse φTX and the reset pulse φRST change from the H level to the L level, so that the transmission transistors 102 and the reset transistors 104 are put in an OFF state. Accordingly, reset of the photoelectric conversion elements 101 of all the pixel units is finished, and exposure (accumulation of signal charges) is started.

(Operation of Time Period T2)

A predetermined time period after the start of exposure, the reset pulse φRST changes to the H level and the L level in a pulse shape, so that the reset transistors 104 change to the ON state and the OFF state. Accordingly, the FDs 103 of all the pixel units are reset. The reset pulse φRST changes from the L level to the H level, and the selection pulse φSEL simultaneously changes from the L level to the H level, so that the selection transistors 107 are put in the ON state. Accordingly, signals of the reset FDs 103 are output to the vertical signal lines 14.

(Operation of Time Period T3)

The transmission pulse φTX changes from the L level to the H level, so that the transmission transistors 102 are put in the ON state. Here, the selection pulse φSEL is maintained at the H level, and thus the selection transistors 107 are maintained in the ON state. Accordingly, signal charges accumulated in the photoelectric conversion elements 101 are output to the vertical signal lines 14.

As described above, the column processing circuits 21 obtain differences between two signals output to the vertical signal lines 14, so that an image signal from which noise has been removed can be obtained. Here, operation of the photoelectric conversion elements 101 corresponding to one row has been described. The same operation is performed on other photoelectric conversion elements 101 in each row in sequence.

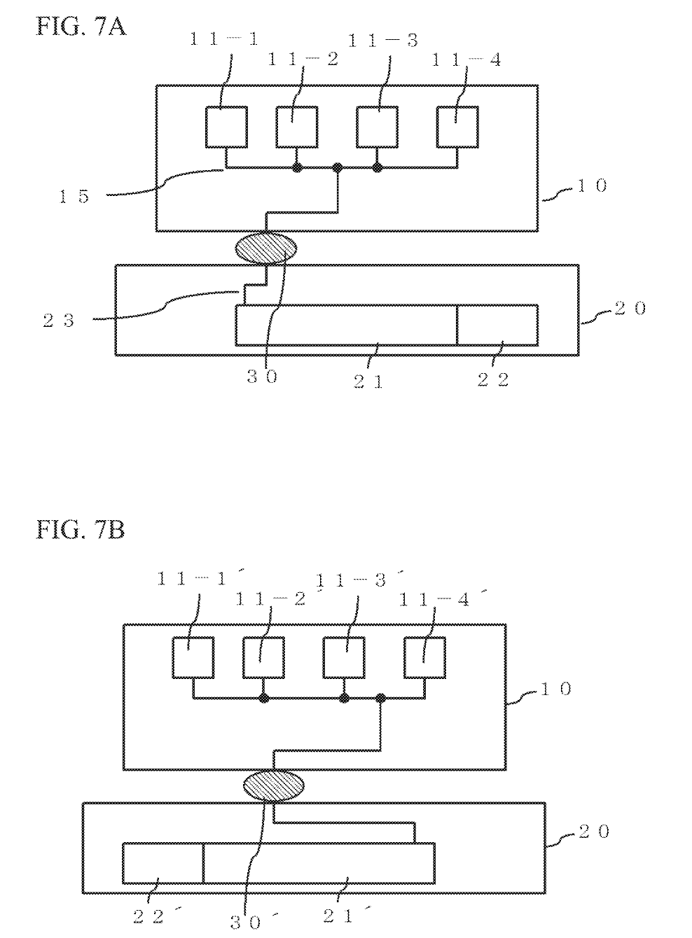

FIG. 7A is a diagram showing wirings from pixel units 11 of an M-th column in the solid-state image pickup device of the present embodiment to a column processing circuit 21.

A pixel unit 11-1 in the M-th column and the first row, a pixel unit 11-2 in the M-th column and the second row, a pixel unit 11-3 in the M-th column and the third row, and a pixel unit 11-4 in the M-th column and the fourth row shown in FIG. 7A are electrically connected to a connection unit 30 through a first wiring 15.

The connection unit 30 is electrically connected to the column processing circuit 21 through a second wiring 23.

Output signals of the pixel units 11-1, 11-2, 11-3, and 11-4 are input to the column processing circuit 21 through the first wiring 15, the connection unit 30, and the second wiring 23.

The column processing circuit 21 performs signal processing including A/D conversion on the output signals of the pixel units 11-1, 11-2, 11-3, and 11-4.

The horizontal scanning circuit 22 reads out the signals processed at the column processing circuit 21.

FIG. 7B is a diagram showing wirings from pixel units 11 of an N-th column in the solid-state image pickup device of the present embodiment to a column processing circuit 21 (M≠N).

A pixel unit 11-1′ in the N-th column and the first row, a pixel unit 11-2′ in the N-th column and the second row, a pixel unit 11-3′ in the N-th column and the third row, and a pixel unit 11-4′ in the N-th column and the fourth row shown in FIG. 7B are electrically connected to a connection unit 30′ through a first wiring 15′.

The connection unit 30′ is electrically connected to the column processing circuit 21′ through a second wiring 23′.

Output signals of the pixel units 11-1′, 11-2′, 11-3′, and 11-4′ are input to the column processing circuit 21′ through the first wiring 15′, the connection unit 30′, and the second wiring 23′. The column processing circuit 21′ performs signal processing including A/D conversion on the output signals of the pixel units 11-1′, 11-2′, 11-3′, and 11-4′.

The horizontal scanning circuit 22′ reads out the signals processed at the column processing circuit 21′.

Here, in the solid-state image pickup device of the present embodiment, column-specific sums of the wiring length of the first wiring 15 and the wiring length of the second wiring 23 are almost the same.

Specifically, the sum (l₁₋₁+l₂) of a wiring length l₁₋₁ of a first wiring 15-1 which connects the pixel unit 11-1 and the connection unit 30 and a wiring length l₂ of the second wiring 23 which connects the connection unit 30 and the column processing circuit 21 is almost the same as the sum (l_{1-1′}+l_{2′}) of a wiring length l_{1-1′} of a first wiring 15-1′ which connects the pixel unit 11-1′ and the connection unit 30′ and a wiring length l_{2′} of a second wiring 23′ which connects the connection unit 30′ and the column processing circuit 21′.

Likewise, the sum (l₁₋₂+l₂) of a wiring length l₁₋₂ of a first wiring 15-2 which connects the pixel unit 11-2 and the connection unit 30 and the wiring length l₂ of the second wiring 23 which connects the connection unit 30 and the column processing circuit 21 is almost the same as the sum (l_{1-2′}+l_{2′}) of a wiring length l_{1-2′} of a first wiring 15-2′ which connects the pixel unit 11-2′ and the connection unit 30′ and the wiring length l_{2′} of the second wiring 23′ which connects the connection unit 30′ and the column processing circuit 21′.

Likewise, the sum (l₁₋₃+l₂) of a wiring length l₁₋₃ of a first wiring 15-3 which connects the pixel unit 11-3 and the connection unit 30 and the wiring length l₂ of the second wiring 23 which connects the connection unit 30 and the column processing circuit 21 is almost the same as the sum (l_{1-3′}+l_{2′}) of a wiring length l_{1-3′} of a first wiring 15-3′ which connects the pixel unit 11-3′ and the connection unit 30′ and the wiring length l_{2′} of the second wiring 23′ which connects the connection unit 30′ and the column processing circuit 21′.

Likewise, the sum (l₁₋₄+l₂) of a wiring length l₁₋₄ of a first wiring 15-4 which connects the pixel unit 11-4 and the connection unit 30 and the wiring length l₂ of the second wiring 23 which connects the connection unit 30 and the column processing circuit 21 is almost the same as the sum (l_{1-4′}+l_{2′}) of a wiring length l_{1-4′} of a first wiring 15-4′ which connects the pixel unit 11-4′ and the connection unit 30′ and the wiring length l_{2′} of the second wiring 23′ which connects the connection unit 30′ and the column processing circuit 21′.

The voltage of an output signal from a pixel unit drops due to the wiring resistance of a vertical signal line. For this reason, an offset which varies according to a pixel overlaps an input signal to a column processing circuit 21. Influence of this offset is removed by obtaining a difference between a signal reset at the column processing circuit 21 and a pixel signal. However, the offset suppression ratio of the column processing circuit 21 is not infinite, and thus the offset becomes fixed pattern noise and remains. Further, when the wiring resistance of a vertical signal line varies according to a column, column-specific offsets are different, and fixed pattern noise becomes and appears as vertical stripes. In order to suppress generation of vertical stripes resulting from a voltage drop of a wiring resistance, column-specific wiring resistances of vertical signal lines should be the same. To this end, the column-specific sums of the wiring resistances of a first wiring and a second wiring should be the same to a degree at which results of signal processing performed by the column processing circuits 21 are not affected.

Here, when a voltage drop allowable by the wiring resistances of the first wiring and the second wiring is ΔV, a wiring resistance from the pixel unit 11-1 to the column processing circuit 21 is R₁, a wiring resistance from the pixel unit 11-1′ to the column processing circuit 21′ is R_{1′}, and a current flowing to the first wiring and the second wiring is i, the following relational expression holds for the first column.

ΔV≧i(R_{1′}−R₁) (Expression 1)

When the resistivity of a wiring is ρ and the cross-sectional area of the wiring is S, the wiring resistance R₁ from the pixel unit 11-1 to the column processing circuit 21 can be expressed by the following expression.

R₁=ρ·(l₁₋₁+l₂)/S (Expression 2)

When the resistivity of a wiring is ρ′ and the cross-sectional area of the wiring is S′, the wiring resistance R_{1′} from the pixel unit 11-1′ to the column processing circuit 21′ can be expressed by the following expression.

R_{1′}=ρ′·(l_{1-1′}+l_{2′})/S′ (Expression 3)

When Expression 2 and Expression 3 are inserted into Expression 1, the following relational expression holds.

ρ·(l_{1-1′}+l_{2′})/S−ρ′·(l₁₋₁+l₂)/S′≦ΔV/i (Expression 4)

Here, (l_{1-1′}+l_{2′}) is the sum of the wiring lengths of the first wiring and the second wiring in the first column and an N-th row, and (l₁₋₁+l₂) is the sum of the wiring lengths of the first wiring and the second wiring in the first column and an M-th row. A difference between them may be equal to or smaller than a value shown on the right side of Expression 4.

For example, when the voltage drop ΔV allowable by the wiring resistances of the first wiring and the second wiring is set to a value obtained by converting the resolution of A/D conversion into the output range of the photoelectric conversion elements 101, ΔV is as follows.

ΔV=(output range of photoelectric conversion element)/(resolution of A/D conversion) (Expression 5)

Here, when the output range of the photoelectric conversion elements is 1.2 [V] and the resolution of A/D conversion is 12 bits, Expression 5 is as follows.

ΔV=1.2 [V]/2¹² (Expression 6)

Also, when both the first wiring and the second wiring are formed of aluminum (ρ=ρ′=2.65×10⁻⁸ [Ω/m]), the thickness of the wirings is 0.25×10⁻⁶ [m], a wiring width is 0.25×10⁻⁶ [m] (S=S′=0.25×10⁻⁶ [m]×0.25×10⁻⁶ [m]), the current i flowing to the first wiring and the second wiring is 6.0×10⁻⁶ [A], and ΔV is the value of Expression 6, Expression 4 is as follows.

(l_{1-1′}+l_{2′})−(l₁₋₁+l₂)≦1.15×10⁻³ [m] (Expression 7)

In this case, when the difference between column-specific sums of wiring lengths of the first wiring and the second wiring is equal to or smaller than 1.15×10⁻³ [m], the column-specific wiring lengths of the first wiring and the second wiring are almost the same.

The above calculation has shown an example in which the column-specific wiring lengths of the first wiring and the second wiring are almost the same. For example, when the first wiring and the second wiring are formed of copper, the resistivity ρ in Expression 2 and Expression 3 may be calculated as the resistivity of copper (1.68×10⁻⁸ [Ω/m]).

Also, in the above calculation, the current i flowing to the first wiring and the second wiring was 6.0×10⁻⁶ [A]. However, when the current i flowing to the first wiring and the second wiring has different current values, the calculation may be made by inserting the different current values into Expression 4.

Further, in the above calculation, the calculation was made by setting the output ranges of photoelectric conversion elements to 1.2 V and the resolution of A/D conversion to 12 bits, but the calculation is not limited thereto. When the output ranges of photoelectric conversion elements or the resolutions of A/D conversion have different values, the calculation may be made by inserting appropriate different current values into Expression 5.

Moreover, in the above calculation, a case in which the cross-sectional areas S of wirings are the same has been described, but the calculation is not limited thereto. When wiring widths, wiring thicknesses, or the like are different column by column, the calculation may be made by appropriately changing the cross-sectional areas S and S′ in Expression 2 and Expression 3.

In this way, in the solid-state image pickup device 1 of the present embodiment, column-specific sums of the wiring length of the first wiring and the second wiring length are almost the same, so that column-specific wiring resistances from a pixel unit 11 to a column processing circuit 21 are almost the same. For this reason, when the same amount of light is input to pixel units 11, column-specific signals output from the column processing circuits 21 are the same. Therefore, it is possible to suppress the irregularity of voltage drops generated by differences in the wiring resistances of respective columns, and it is possible to suppress noise resulting from the irregularity of voltage drops.

For the above reasons, the solid-state image pickup device 1 of the present embodiment can generate a high quality image signal.

### Second Embodiment

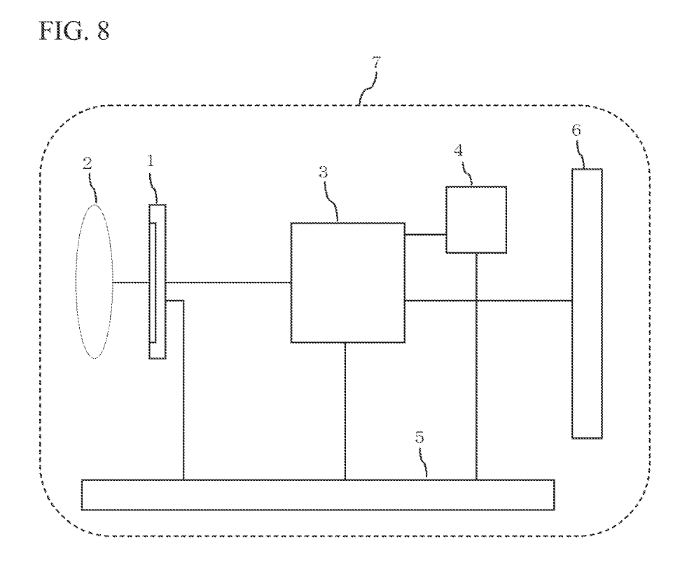

Next, an image pickup device equipped with the solid-state image pickup device 1 of the first embodiment will be described. FIG. 8 is a block diagram showing a schematic configuration of an image pickup device (for example, a digital single-lens camera, an endoscope, a microscope, or the like) equipped with a solid-state image pickup device 1 according to an embodiment of the present invention.

An image pickup device 7 shown in FIG. 8 includes a lens unit portion 2, a solid-state image pickup device 1, an image signal processing device 3, a recording device 4, a camera control device 5, and a display device 6.

Zooming, the focus, the aperture, and the like of the lens unit portion 2 are drive-controlled by the camera control device 5, and the lens unit portion 2 causes a subject image to be imaged on the solid-state image pickup device 1.

The solid-state image pickup device 1 is the solid-state image pickup device 1 of the first embodiment. The solid-state image pickup device 1 is driven and controlled by the camera control device 5 to convert subject light incident on the solid-state image pickup device 1 through the lens unit portion 2 into an electric signal and output the image signal corresponding to the amount of incident light to the image signal processing device 3.

The image signal processing device 3 performs processes, such as signal amplification, conversion into image data and various types of correction, compression of the image data, and the like, on the image signal input from the solid-state image pickup device 1. The image signal processing device 3 uses a memory which is not shown in the drawing as a means for temporarily storing image data in each process.

The recording device 4 is a detachable recording medium, such as a semiconductor memory, and performs the recording or the readout of image data.

The camera control device 5 is a control device that performs overall control of the image pickup device 7.

The display device 6 is a display device, such as liquid crystal, that displays an image based on image data imaged on the solid-state image pickup device 1 and processed by the image signal processing device 3 or image data read out from the recording device 4.

As described above, the image pickup device 7 is equipped with the solid-state image pickup device 1 of the first embodiment. Accordingly, the image signal processing device 3 provided in the image pickup device 7 of the present embodiment can generate image data in which noise resulting from the irregularity of column-specific wiring resistances has been suppressed. In this way, the image pickup device 7 of the present embodiment can output high quality image data.

Here, a detailed configuration of the present invention is not limited to an embodiment of the present invention, and can be modified in various ways within a range not departing from the gist of the present invention. Also, detailed configurations of a circuit configuration and a drive method in the present invention are not limited to embodiments of the present invention, and can be modified in various ways within a range not departing from the gist of the present invention.

Further, a disposition of unit pixels in a row direction and a column direction is not limited to the embodiments of the present invention, and it is possible to change the numbers of unit pixels disposed in the row direction and the column direction within a range not departing from the gist of the present invention.

Moreover, in a solid-state image pickup device relating to an embodiment of the present invention, two substrates may be connected by connection units, or three or more substrates may be connected by connection units. When three or more substrates are connected by connection units, two of them correspond to a first substrate and a second substrate relating to the claims.

Embodiments of the present invention have been described above with reference to the drawings, but a detailed configuration is not limited to these embodiments and includes various modifications within a range not departing from the gist of the present invention.

The present invention can be widely applied to solid-state image pickup devices and image pickup devices, and enables suppression of vertical stripe noise resulting from the irregularity of column-specific wiring resistances and suppression of degradation of image quality.

What is claimed is:

1. A solid-state image pickup device in which a first substrate and a second substrate are laminated and electrically connected by connection units,
wherein the first substrate comprises:
a plurality of pixel units which are disposed in a matrix shape and output signals corresponding to amounts of incident light; and
first wiring units which connect the pixel units and the connection units,
the second substrate comprises:
column processing circuits which process the signals generated by the pixel units; and
second wiring units which connect the connection units and the column processing circuits, and
wherein sum of a wiring resistance of a first wiring unit and a wiring resistance of a second wiring unit are almost identical in each column.

2. The solid-state image pickup device of claim 1, wherein sum of a wiring length of a first wiring unit and a wiring length of a second wiring unit are almost identical in each column.

3. An image pickup device comprising the solid-state image pickup device according to claim 1.

4. An image pickup device comprising the solid-state image pickup device according to claim 2.
